(19) United States
(12) Patent Application Publication
(10) Pub. No.: US 2022/0316088 A1
(43) Pub. Date: Oct. 6, 2022

(54) Molecular Beam Epitaxial Growth Apparatus, Crystal Growth Method And Method For Manufacturing Light Emitter

(71) Applicant: Seiko Epson Corporation, Tokyo (JP)

(72) Inventor: Hiroyuki SHIMADA, Chuo (JP)

(21) Appl. No.: 17/706,669

(22) Filed: Mar. 29, 2022

(30) Foreign Application Priority Data
Mar. 30, 2021 (JP) 2021-056840

(51) Int. Cl. C30B 23/02; H01L 33/00; C30B 23/00; C23C 14/28; C23C 14/54; C23C 14/06; C30B 29/40

(52) U.S. Cl. CPC C30B 23/02; H01L 33/0075; C30B 23/002; C23C 14/28; C23C 14/54; C23C 14/0617; C30B 29/406; C30B 29/403

(57) ABSTRACT

A molecular beam epitaxial growth apparatus of the present disclosure includes a stage, a first molecular beam source irradiates a substrate surface with a first molecular beam, a second molecular beam source irradiates the substrate surface with a second molecular beam, a shutter shields the first molecular beam or the second molecular beam, and a control unit controls the shutter and relative positions of the stage with respect to the first molecular beam source and the second molecular beam source. The radiation direction of the first molecular beam emitted from the first molecular beam source and the radiation direction of the second molecular beam emitted from the second molecular beam source are vertical to the substrate surface. Under the control of the control unit, the second molecular beam is shielded while the first molecular beam is radiated on the substrate surface, and the first molecular beam is shielded while the second molecular beam is radiated on the substrate surface.

The present application is based on, and claims priority from JP Application Serial Number 2021-056840, filed Mar. 30, 2021, the disclosure of which is hereby incorporated by reference herein in its entirety.

### BACKGROUND

### 1. Technical Field

The present disclosure relates to a molecular beam epitaxial growth apparatus, a crystal growth method, and a method for manufacturing a light emitter.

### 2. Related Art

A light emitter provided in an illuminating apparatus such as a projector includes a plurality of crystal columns made of semiconductors. Such crystal columns are manufactured by, for example, crystal-growing semiconductors in a columnar shape using a molecular beam epitaxial growth apparatus (hereinafter, referred to as MBE apparatus) based on a molecular beam epitaxy (MBE) method. Generally, when the crystal columns are grown in a column center direction by the MBE apparatus, a plurality of types of molecular beams including semiconductor materials are uniformly radiated on a surface of a substrate. Thus, a plurality of types of molecular beam sources are arranged such that traveling directions of the plurality of types of molecular beams define a large angle of, for example, about 40° to 45° in a circumferential direction with respect to a reference direction vertical to the surface of the substrate with a target position on the surface of the substrate as a center in a side view. For example, JP-A-05-326404 discloses a MBE apparatus in which two types of molecular beam sources are arranged such that traveling directions of the two types of molecular beams define a predetermined angle with respect to a reference direction vertical to a surface of a substrate with a position on the surface of the substrate as a center in a side view.

With related-art MBE apparatuses, it is difficult to radiate a plurality of types of molecular beams vertically to a surface of a substrate. That is, with the related-art MBE apparatuses, the plurality of types of molecular beams are radiated on the surface of the substrate along an inclined direction with respect to a reference direction vertical to the surface of the substrate. Consequently, as crystal columns grow, width dimensions thereof orthogonal to a column center direction become larger and it becomes difficult to control the width dimensions or make the width dimensions uniform in the column center direction. As a result, the width dimensions of the crystal columns after the MBE process are not uniform in the column center direction, or the width dimensions of top portions of the crystal columns in the column center direction are larger than the width dimensions of bottom portions, and thus light emitting efficiency of the light emitter may decrease.

### SUMMARY

In order to solve the above-described problems, a MBE apparatus according to one embodiment of the present disclosure includes a stage on which an object including a substrate is mounted, a first molecular beam source configured to irradiate the object with a first molecular beam, a second molecular beam source configured to irradiate the object with a second molecular beam, a shutter configured to shield the first molecular beam or the second molecular beam, and a control unit configured to control operations of the shutter and relative positions of the stage with respect to the first molecular beam source and the second molecular beam source. Under the control of the control unit, the second molecular beam is shielded while the first molecular beam is radiated on the surface, and the first molecular beam is shielded while the second molecular beam is radiated on the surface.

### BRIEF DESCRIPTION OF THE DRAWINGS

FIG. 1 is a plan view of a light emitter manufactured by using a MBE apparatus according to a first embodiment.

FIG. 2 is a cross-sectional view taken along a line I-I of the light emitter shown in FIG. 1.

FIG. 3 is an enlarged plan view of a region RR including a light emitting unit of the light emitter shown in FIG. 2.

FIG. 4 is a cross-sectional view showing a process of a method for manufacturing the light emitter shown in FIG. 2.

FIG. 5 is a schematic cross-sectional view of the MBE apparatus according to the first embodiment.

FIG. 6 is a plan view of a shutter body and a plurality of types of molecular beam sources of the MBE apparatus shown in FIG. 5.

FIG. 7 is a plan view of another shutter body of the MBE apparatus shown in FIG. 5.

FIG. 8 is a plan view of the shutter body at a timing different from a timing of FIG. 7.

FIG. 9 is a plan view of the shutter body and the plurality of types of molecular beam sources at a timing different from a timing of FIG. 6.

FIG. 10 is a cross-sectional view showing a process of a method for manufacturing the light emitter shown in FIG. 2.

FIG. 11 is a schematic view of main parts of the MBE apparatus according to the first embodiment.

FIG. 12 is a schematic view of main parts of a related-art MBE apparatus.

FIG. 13 is a schematic side view of a MBE apparatus according to a second embodiment.

FIG. 14 is a schematic side view of the MBE apparatus according to the second embodiment at a timing different from a timing of FIG. 13.

### DESCRIPTION OF EXEMPLARY EMBODIMENTS

### First Embodiment

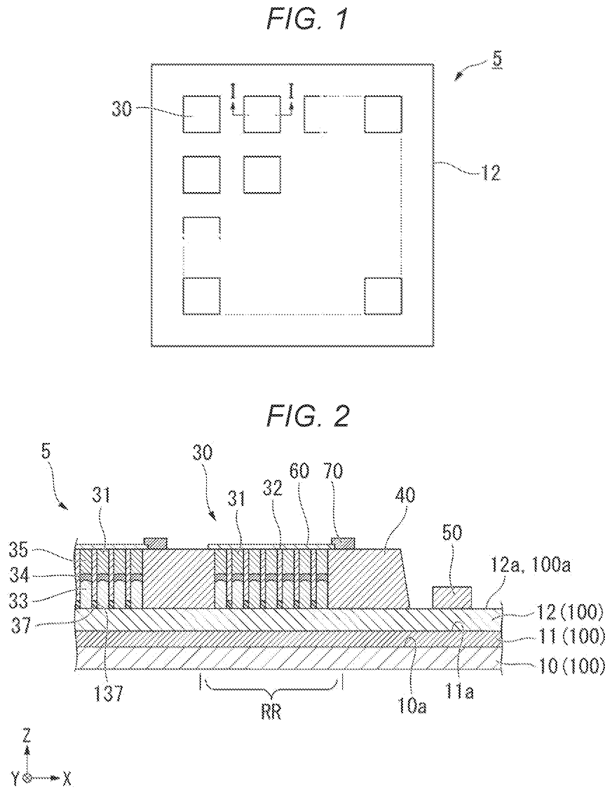

Hereinafter, a first embodiment of the present disclosure will be described with reference to FIGS. 1 to 6.

In the drawings below, the scale of dimensions may be changed depending on components in order to make the components easier to see.

### Basic Structure of Light Emitter

FIG. 1 is a plan view of a light emitter 5 that is an example of a light emitter that can be manufactured by a MBE apparatus according to the present embodiment. As shown in FIG. 1, the light emitter 5 according to the present embodiment is used, for example, in a projector (not shown), and directly forms an image by modulation according to image information. In FIG. 1, when seen from a traveling direction of light emitted by the light emitter 5, two directions that are included in a surface 50a of the light emitter 5 and are orthogonal, are defined as X direction and Y direction. A direction that is orthogonal to the X and Y directions and is the traveling direction of the light emitted from the light emitter 5, that is, a direction parallel to an optical axis, is defined as Z direction.

As shown in FIG. 1, the light emitter 5 includes a plurality of light emitting units 30 arranged in an array. The plurality of light emitting units 30 are arranged in a matrix along the X direction and the Y direction. The light emitter 5 constitutes a self-luminous imager that forms an image with each of the light emitting units 30 as one pixel.

FIG. 2 is a cross-sectional view of the light emitter 5 viewed by a line I-I shown in FIG. 1. As shown in FIG. 2, the light emitter 5 includes a substrate body 10, a reflective layer 11, a semiconductor layer 12, the light emitting unit 30, an insulating layer 40, a first electrode 50, a second electrode 60, and wirings 70.

The substrate body 10 is constituted by, for example, a silicon (Si) substrate, a gallium nitride (GaN) substrate, or a sapphire substrate. The reflective layer 11 is provided at a surface 10a of the substrate body 10. The reflective layer 11 is constituted by, for example, a stacked body in which AlGaN layers and GaN layers are alternately stacked, or a stacked body in which AlInN layers and GaN layers are alternately stacked. The reflective layer 11 reflects light generated by a light emitting layer 34, which will be described later, in the Z direction toward a side opposite to the substrate body 10. A heat sink for releasing heat generated by the light emitting unit 30 may be provided at a lower surface 10b of the substrate body 10.

The semiconductor layer 12 is provided at a surface 11a of the reflective layer 11. The semiconductor layer 12 is a layer made of an n-type semiconductor material, and is constituted by, for example, an n-type GaN layer, which is specifically a Si-doped GaN layer.

The light emitting unit 30 includes a plurality of nanocolumns (crystal columns) 31 and light propagation layers 32. The nanocolumns 31 are columnar crystal structures protruding and extending in the Z direction from a surface 12a of the semiconductor layer 12. That is, crystal growth directions and column center directions of the nanocolumns 31 are vertical to the surface 10a of the substrate body 10 and the surface 12a of the semiconductor layer 12, and are parallel to the Z direction. Shapes in a plan view of the nanocolumns when seen from the Z direction may be, for example, polygonal columnar shapes, cylindrical columnar shapes, or elliptical columnar shapes. In the present embodiment, the shapes of the nanocolumns 31 are cylindrical columnar shapes. Width dimensions of the nanocolumns 31 in a direction orthogonal to the Z direction are on the order of nanometer, and specifically, for example, 10 nm or more and 500 nm or less. Height dimensions of the nanocolumns 31 in the Z direction are, for example, 0.1 μm or more and 5 μm or less.

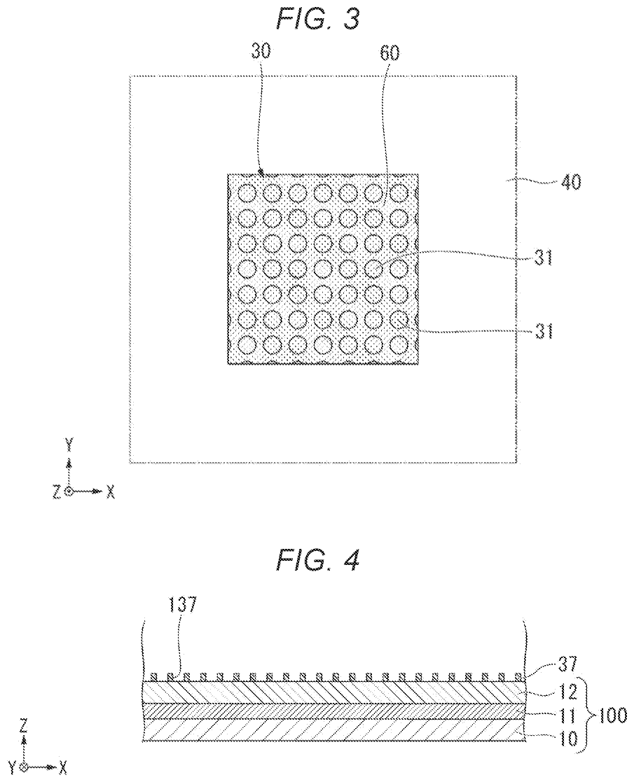

FIG. 3 is an enlarged plan view of a region RR that is shown in FIG. 2 and includes one light emitting unit 30 of the light emitter 5. As shown in FIG. 3, the plurality of nanocolumns 31 are aligned at a predetermined pitch along predetermined directions in an XY plane including the X direction and the Y direction. In the present embodiment, the predetermined directions are the X direction and the Y direction. The nanocolumns 31 exhibit an effect of photonic crystals, confine the light emitted by the light emitting layer 34 in in-plane directions of the substrate body 10, and emit the light in a stacking direction of the substrate body 10.

Each of the nanocolumns 31 includes a first semiconductor layer 33, the light emitting layer 34, and a second semiconductor layer 35. Specifically, the nanocolumn 31 has a stacked structure in which the first semiconductor layer 33, the light emitting layer 34, and the second semiconductor layer 35 are sequentially stacked from the surface 12a of the semiconductor layer 12 in the Z direction. The layers constituting the nanocolumn 31 are formed by the MBE method as described later.

The first semiconductor layer 33 is provided at the surface 12a of the semiconductor layer 12. The first semiconductor layer 33 is provided between the semiconductor layer 12 and the light emitting layer 34 in the Z direction. The first semiconductor layer 33 is an n-type semiconductor layer, and is constituted by, for example, a Si-doped n-type GaN layer.

The light emitting layer 34 is provided at the first semiconductor layer 33. The light emitting layer 34 is provided between the first semiconductor layer 33 and the second semiconductor layer 35 in the Z direction. The light emitting layer 34 has, for example, a quantum well structure in which a large number of GaN layers and InGaN layers are alternately stacked. The light emitting layer 34 emits light by injecting an electric current through the first semiconductor layer 33 and the second semiconductor layer 35. The number of GaN layers and InGaN layers constituting the light emitting layer 34 is not particularly limited. The light emitting layer 34 emits blue light in the blue wavelength band of, for example, 430 nm to 470 nm.

The second semiconductor layer 35 is provided at the light emitting layer 34. The second semiconductor layer 35 has a conductive type different from the first semiconductor layer 33. That is, the second semiconductor layer 35 is a layer made of a p-type semiconductor material, and is constituted by, for example, an Mg-doped p-type GaN layer. The first semiconductor layer 33 and the second semiconductor layer 35 function as clad layers having a function of confining light in the light emitting layer 34 in the Z direction.

The light propagation layers 32 surround each of the nanocolumns 31 in a plan view as seen from the Z direction. Therefore, the light propagation layers 32 are provided in gaps between adjacent nanocolumns 31 in the XY plane. The refractive index of the light propagation layers 32 is lower than that of the light emitting layer 34. The light propagation layers 32 are constituted by, for example, GaN layers or titanium oxide (TiO₂) layers. The GaN layers constituting the light propagation layers 32 may be i-type, n-type, or p-type. The light propagation layers 32 propagate the light generated in the light emitting layer 34 in the plane direction.

In the light emitting unit 30, a pin diode is constituted by a stacked body of the p-type second semiconductor layer 35, the light emitting layer 34 without impurities doping, and the n-type first semiconductor layer 33. In the light emitting unit 30, when a voltage equivalent to a forward bias voltage of the pin diode is applied between the first electrode 50 and the second electrode 60 to inject an electric current, recombination of electrons and holes occurs in the light emitting layer 34. The recombination causes light emission.

The light generated in the light emitting layer 34 is propagated by the first semiconductor layer 33 and the second semiconductor layer 35 through the light propagation layers 32 in a direction parallel to the surface 10a of the substrate body 10. At this time, the light forms a standing wave due to the effect of the photonic crystals by the nanocolumns 31, and is confined in the direction parallel to the surface 10a of the substrate body 10. The confined light receives a gain in the light emitting layer 34 and laser oscillation occurs. The refractive index and thickness of the first semiconductor layer 33, the second semiconductor layer 35, and the light emitting layer 34 in the light emitter 5 are designed such that the intensity of the light propagated in the direction parallel to the surface 10a of the substrate body 10 is largest in the light emitting layer 34 in the Z direction. Laser light traveling toward the substrate body 10 included in the laser light traveling in the stacking direction is reflected by the reflective layer 11 and travels toward the second electrode 60. As a result, the light emitting unit 30 can emit light from a surface 60a of the second electrode 60.

As shown in FIG. 2, mask layers 37 are provided at the semiconductor layer 12. The mask layers 37 are provided between the light propagation layers 32 and the semiconductor layer 12 in the Z direction. The mask layers 37 function as masks for selectively growing films, which constitute the nanocolumns 31, in specific regions on the semiconductor layer 12 in the manufacturing process of the light emitting unit 30. The mask layers 37 are constituted by, for example, silicon oxide layers or silicon nitride layers.

The insulating layer 40 is provided between adjacent light emitting units 30 at the surface 12a of the semiconductor layer 12. The insulating layer 40 is constituted by, for example, a silicon oxide layer. The insulating layer 40 has functions of flattening unevenness on the semiconductor layer 12 formed due to the light emitting units 30 and protecting the light emitting units 30.

The first electrode 50 is electrically coupled to the first semiconductor layer 33 of the nanocolumn 31 via the semiconductor layer 12. The first electrode 50 is an electrode on one side for injecting the electric current into the light emitting layer 34. The first electrode 50 is constituted by, a metal layer made of Ni, Ti, Cr, Pt or Au, or a stacked metal film in which Ni, Ti, Cr, Pt or Au are stacked.

The second electrode 60 is provided at a surface 30a of the light emitting unit 30. The second electrode 60 is an electrode on the other side for injecting the electric current into the light emitting layer 34. The second electrode 60 is provided in a region corresponding to the light emitting unit 30 in the XY plane. The second electrode 60 is in contact with a part of the nanocolumn 31 and the light propagation layers 32. The second electrode 60 has conductivity and light transmission. Thus, the second electrode 60 is constituted by a metal layer made of Ni, Ti, Cr, Pt or Au, a stacked metal film in which Ni, Ti, Cr, Pt or Au are stacked, a transparent conductive layer made of indium tin oxide (ITO) or indium zinc oxide (IZO), and the like.

The wirings 70 are coupled to a drive circuit (not shown) provided in a predetermined region at the surface 10a of the substrate body 10 via, for example, a bonding wire. The first electrode 50 is coupled to the drive circuit provided in the region that is not shown at the substrate body 10 via, for example, the bonding wire. Based on such a configuration, the light emitting unit 30 can inject the electric current into the light emitting layer 34 of the nanocolumn 31 via the first electrode 50 and the second electrode 60 by driving the drive circuit.

### Method for Manufacturing Light Emitter, Crystal Growth Method, and Basic Structure of MBE Apparatus

Next, a method for manufacturing the light emitter 5 will be described. FIG. 4 is a cross-sectional view showing a process of the method for manufacturing the light emitter 5. First, a metal film is formed at the surface 10a of the substrate body 10 by, for example, a sputtering method or a vapor deposition method to form the reflective layer 11. Next, the semiconductor layer 12 is formed at the surface 11a of the reflective layer 11 by epitaxial growth. Examples of the epitaxial growth method include a metal organic chemical vapor deposition (MOCVD) method and the MBE method.

As shown in FIG. 4, the mask layer 37 having numerous openings 137 is then formed at the surface 12a of the semiconductor layer 12. The mask layer 37 is formed, for example, by film formation using a chemical vapor deposition (CVD) method or the sputtering method, or by patterning of photolithography and etching.

Subsequently, the nanocolumns 31 are formed respectively in the numerous openings 137 formed in the mask layer 37. In the process of forming the nanocolumns 31, the stacked structure including the substrate body 10, the reflective layer 11, the semiconductor layer 12, and the mask layer 37 is treated as a substrate 100. In the process of forming the plurality of nanocolumns 31, the nanocolumns 31 are grown and extended along the vertical direction, that is, the Z direction, at a surface 100a of the substrate 100, that is, exposed parts of the surface 12a of the semiconductor layer 12. The “substrate surface of a substrate” in the claims corresponds to the surface 100a of the substrate 100.

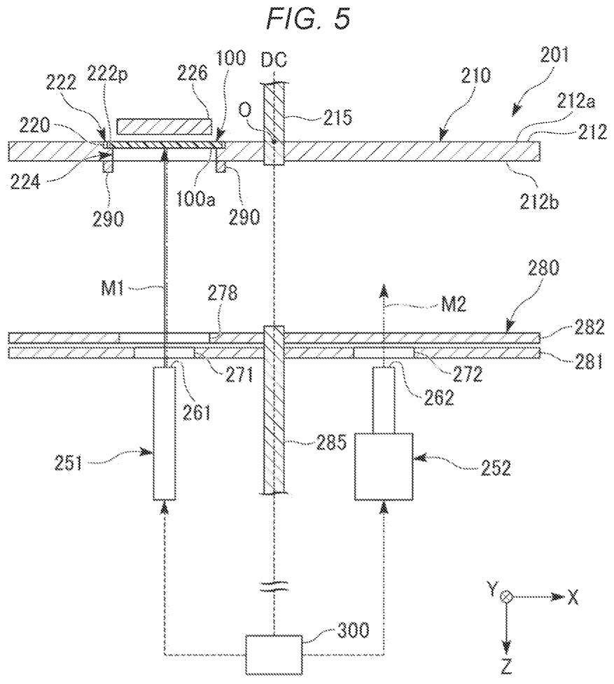

FIG. 5 is a cross-sectional view of a molecular beam epitaxial growth apparatus (MBE apparatus) 201 according to the first embodiment used in the process of forming the plurality of nanocolumns 31 as seen from the Y direction. As shown in FIG. 5, the MBE apparatus 201 includes a stage 210, at least a first molecular beam source 251 and a second molecular beam source 252, a shutter 280, and a control unit 300.

The stage 210 is provided for mounting an object for crystal growth. In the present embodiment, the substrate 100 is mounted as the object. The object for crystal growth may be the substrate itself, or may be a substrate provided in advance with a structure such as a functional element. In other words, the object may have a substrate. The stage 210 according to the first embodiment is rotatable (movable in a predetermined direction) in the XY plane. Specifically, the stage 210 according to the first embodiment includes a stage body 212 formed in a plate shape that is also a disk shape when seen from the Z direction. The stage body 212 is made of, for example, stainless steel (SUS). The stage body 212 is supported by a shaft core member 215 and is rotatable about a center O of a plate surface 212a of the stage body 212 and a shaft core direction DC of the shaft core member 215.

A mounting portion 220 on which the substrate 100 is mounted is provided at the plate surface (one plate surface) 212a of the stage body 212. The mounting portion 220 includes a recess portion 222 formed at the plate surface 212a of the stage body 212. The shape in the XY plane of the recess portion 222 is the same as the shape in the XY plane of the substrate 100 mounted on the recess portion 222. The opening dimension in the XY plane of the recess portion 222 is slightly larger than the dimension in the XY plane of the substrate 100. The depth dimension of the recess portion 222 is smaller than the thickness of the stage body 212.

In a region of a plate surface 212b that overlaps the recess portion 222 in a direction parallel to the plate surfaces 212a and 212b of the stage body 212, a molecular beam through hole 224 is formed. The molecular beam through hole 224 communicates with the recess portion in the Z direction. The shape of the recess portion 222 in the XY plane is the same as the shape of the region where the plurality of openings 137 are formed in the XY plane of the substrate 100. The opening dimension in the XY plane of the molecular beam through hole 224 is smaller than the opening dimension in the XY plane of the recess portion 222. The center of the molecular beam through hole 224 seen from the Z direction substantially overlaps the center of the recess portion 222 seen from the Z direction. In the first embodiment, the shape in the XY plane of the region where the plurality of openings 137 of the substrate 100 are formed, and the shapes in the XY plane of the recess portion 222 and the molecular beam through hole 224 are circular shapes.

At the mounting portion 220, the substrate 100 is mounted in the recess portion 222 by abutting an outer peripheral edge portion of the surface 100a of the substrate 100 against a bottom surface 222p of the recess portion 222. When the substrate 100 is mounted on the recess portion 222, the mask layer 37 at the surface 100a of the substrate 100 and the semiconductor layer 12 exposed to the openings 137 are exposed to the molecular beam through hole 224. In FIG. 5, the detailed structure of the substrate 100 is omitted. In the Z direction, a heater 226 is provided at a side opposite to a side where the region of the plate surface 212b overlaps the recess portion 222 and the molecular beam through hole 224 is formed to the recess portion 222. The heater 226 moves together with the recess portion 222 while maintaining the overlap with the recess portion 222 of the mounting portion 220 in the Z direction when the stage body 212 rotates.

Detectors 290 that detect radiation amounts of types of molecular beams radiated to the surface 100a of the substrate 100 are provided at the plate surface 212b of the stage body 212 near the molecular beam through hole 224.

The first molecular beam source 251 and the second molecular beam source 252 irradiate the surface 100a exposed to the molecular beam through hole 224 of the substrate 100 mounted on the recess portion 222 of the mounting portion 220 with a first molecular beam M1 and a second molecular beam M2, respectively. The first molecular beam M1 and the second molecular beam M2 contain gallium (Ga) and nitrogen (N) as materials of, for example, the first semiconductor layer 33 of the nanocolumn 31. That is, the first molecular beam source 251 irradiates the surface 100a of the substrate 100 with a Ga molecular beam as the first molecular beam M1. The second molecular beam source 252 irradiates the surface 100a of the substrate 100 with an N molecular beam as the second molecular beam M2, specifically, an RF-N₂ molecular beam. The first molecular beam source 251 to a sixth molecular beam source cannot be moved or rotated.

In the MBE apparatus 201 according to the first embodiment, radiation directions of the plurality of types of molecular beams radiated from the plurality of molecular beam sources are preferably vertical to the surface 100a of the substrate 100, which do not have to be vertical, and are preferably close to being vertical. The radiation direction of the first molecular beam M1 radiated from the first molecular beam source 251 is parallel to the Z direction. The radiation direction of the second molecular beam M2 radiated from the second molecular beam source 252 is parallel to the Z direction. The radiation directions of a third molecular beam, a fourth molecular beam, a fifth molecular beam, a sixth molecular beam radiated from a third molecular beam source to the sixth molecular beam source are also parallel to the Z direction. That is, in the MBE apparatus 201 according to the first embodiment, the radiation directions of the plurality of types of molecular beams radiated from the plurality of molecular beam sources are all vertical to the surface 100a of the substrate 100 and parallel to the Z direction. Here, the fact that the radiation directions of the plurality of types of molecular beams are vertical to the surface 100a of the substrate 100 means that the width dimension of the nanocolumn 31 in the direction orthogonal to the growth direction and the column center direction is substantially uniform in the Z direction. Therefore, an angle between the direction vertical to the surface 100a of the substrate 100, that is, the Z direction, and the radiation directions of the plurality of types of molecular beams including the first molecular beam M1 and the second molecular beam M2 is at least 90°±5°, preferably 90°±2°, and most preferably 90°.

The shutter 280 shields the first molecular beam M1 or the second molecular beam M2. Specifically, the shutter 280 according to the first embodiment includes a shutter body (first shutter body) 281 and a shutter body (second shutter body) 282 formed in a plate shape which is also a disk shape when seen from the Z direction. The shutter bodies 281 and 282 are made of, for example, SUS. The shutter bodies 281, 282 are supported by a shaft core member 285. The shaft core member 285 is arranged coaxially with the shaft core member 215. The center of the shutter bodies 281, 282 seen from the Z direction overlaps the center O of the stage body 212 seen from the Z direction. In the following description, the centers of the stage body 212, the shutter bodies 281 and 282 seen from the Z direction will be collectively referred to as the center O.

The shutter body 282 is arranged between the stage body 212 and the shutter body 281 in the Z direction (thickness direction of the stage body), and more specifically, arranged adjacent to the shutter body 281 at a position closer to the shutter body 281 than the stage body 212 in the Z direction. The shutter body 281 is not rotatable. The shutter body 282 is rotatable independently of the center O and the shaft core direction DC of the shaft core member 285.

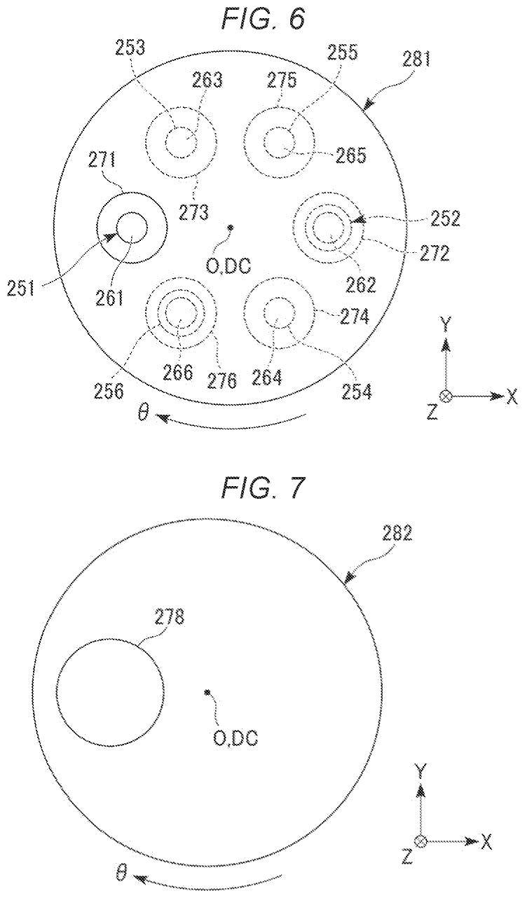

FIG. 6 is a plan view of the shutter body 281 of the shutter 280 and the region where the first molecular beam source 251 and the second molecular beam source 252 are arranged as seen from the Z direction. FIG. 7 is a plan view of the shutter body 282 of the shutter 280 in the MBE apparatus 201 according to the first embodiment as seen from the Z direction. As shown in FIG. 6, the MBE apparatus 201 includes, in addition to the first molecular beam source 251 and the second molecular beam source 252, a third molecular beam source 253, a fourth molecular beam source 254, a fifth molecular beam source 255 and a sixth molecular beam source 256. The third molecular beam source 253 irradiates the surface 100a of the substrate 100 with a Si molecular beam as the third molecular beam. The fourth molecular beam source 254 irradiates the surface 100a of the substrate 100 with a Ga molecular beam similar to the first molecular beam M1 as the fourth molecular beam. The fifth molecular beam source 255 irradiates the surface 100a of the substrate 100 with an Mg molecular beam as the fifth molecular beam. The sixth molecular beam source 256 irradiates the surface 100a of the substrate 100 with an RF-N₂ molecular beam similar to the second molecular beam M2 as the sixth molecular beam. Si or Mg is a dopant for forming the nanocolumn 31 by crystal growth. Si is an n-type GaN dopant and Mg is a p-type GaN dopant.

The first molecular beam source 251 to the sixth molecular beam source 256 are provided such that molecular beam radiation ports 261 to 266 are arranged concentrically when seen from the Z direction with respect to the center O, and are arranged at substantially equal intervals in a circumferential direction θ with respect to the center O. FIG. 5 shows only the first molecular beam source 251 and the second molecular beam source 252 among the first molecular beam source 251 to the sixth molecular beam source 256.

In the MBE apparatus 201, as shown in FIG. 6, starting form the first molecular beam source 251, the third molecular beam source 253, the fifth molecular beam source 255, the second molecular beam source 252, the fourth molecular beam source 254, and the sixth molecular beam source 256 are sequentially arranged in the circumferential direction θ, that is, clockwise. The order of arrangement of these molecular beam sources in the circumferential direction θ, however, is not particularly limited, and it may be sequentially arranged along the circumferential direction θ in an order of, for example, the first molecular beam source 251, the second molecular beam source 252, the third molecular beam source 253, the fourth molecular beam source 254, the fifth molecular beam source 255, and the sixth molecular beam source 256.

As shown in FIGS. 5 and 6, the shutter body 281 is formed with molecular beam passage holes (first molecular beam passage hole, second molecular beam passage hole) 271 to 276 penetrating in the Z direction. The molecular beam passage hole (first molecular beam passage hole) 271 is formed at a position overlapping the molecular beam radiation port 261 of the first molecular beam source 251 in the direction parallel to the surface 100a of the substrate 100, that is, in the direction parallel to the XY plane. The molecular beam passage hole (second molecular beam passage hole) 272 is formed at a position overlapping the molecular beam radiation port 262 of the second molecular beam source 252 in a direction parallel to the surface 100a of the substrate 100. Similarly, as shown in FIG. 6, the molecular beam passage holes 273 to 276 are formed at positions parallel to the surface 100a of the substrate 100 and overlapping the molecular beam radiation ports 263 to 266 of the third molecular beam source 253 to the sixth molecular beam source 256.

As shown in FIGS. 5 and 7, the shutter body 282 is formed with a molecular beam passage hole 278 penetrating in the Z direction. The molecular beam passage hole 278 overlaps any of the molecular beam radiation ports 261 to 266 of the first molecular beam source 251 to the sixth molecular beam source 256 in the Z direction by the rotation of the shutter body 282 with respect to the center O.

The shape in the XY plane of the molecular beam passage holes 271 to 276 is the same as the shape in the XY plane of the molecular beam radiation ports 261 to 266, and is, for example, a circular shape. The opening dimension in the XY plane of the molecular beam passage holes 271 to 276 is larger than the dimension in the XY plane of the molecular beam radiation ports 261 to 266. On the other hand, the shape in the XY plane of the molecular beam passage hole 278 is the same as the shape in the XY plane of the molecular beam passage holes 271 to 276. The opening dimension in the XY plane of the molecular beam passage hole 278 is larger than that of any of the molecular beam passage holes 271 to 276 and the molecular beam through hole 224.

The stage body 212 and the shutter body 282 are rotatable independently of each other with respect to the center O. That is, since the stage body 212 and the shutter body 282 rotate independently of each other in the circumferential direction θ, in the direction parallel to the surface 100a of the substrate 100, each of the molecular beam passage holes 271 to 276 can overlap the recess portion 222 of the mounting portion 220 and the molecular beam through hole 224.

The control unit 300 controls an operation of the shutter 280 and a relative position of the stage 210 with respect to the first molecular beam source 251 and the second molecular beam source 252. The control unit 300 is, for example, a personal computer (PC). The control unit 300 according to the first embodiment controls the rotation, which is also the operation of the shutter 280, of the shutter body 282 in the circumferential direction θ with respect to the center O, while controlling the rotation, which is also the relative position of the stage body 212, of the stage body 212 in the circumferential direction θ with respect to the center O with the rotation of the shutter body 282.

The control unit 300 shields, with the shutter 280, the second molecular beam M2 and the third molecular beam to the sixth molecular beam while at least the first molecular beam M1 is radiated on the surface 100a of the substrate 100, and shields, with the shutter 280, the first molecular beam M1 and the third molecular beam to the sixth molecular beam while the second molecular beam M2 is radiated on the surface 100a. That is, under the control of the control unit 300, the rest types of the molecular beams are shielded while the surface 100a of the substrate 100 is irradiated with one type of the molecular beams. The control of the stage 210 and the shutter 280 by the control unit 300 will be described later.

The control unit 300 is coupled, is a wired or wireless way (not shown), to the shaft core members 215 and 285, the plurality of types of the molecular beam sources including the first molecular beam source 251 to the sixth molecular beam source 256, and the detectors 290. The control unit 300 can rotate the stage body 212 to a desired position in the circumferential direction θ via the shaft core member 215, and can rotate the stage 282 to a desired position in the circumferential direction θ independently of the stage body 212 via the shaft core member 285. The control unit 300 can detect in real time at any timing, with the detectors 290, the radiation amount of each type of the molecular beams to the surface 100a of the substrate 100 mounted on the mounting portion 220. It is preferable that the control unit 300 timely confirms, using the detectors 290, whether each type of the molecular beams can be radiated at a predetermined radiation amount from each of the molecular beam sources including the first molecular beam M1, the second molecular beam M2, and the third to sixth molecular beams.

Using the MBE apparatus 201, a plurality of nanocolumns 31 are simultaneously grown along the Z direction vertical to the surface 100a by irradiating the surface 100a of the substrate 100 with the first molecular beam M1 and the second molecular beam M2 by the method for manufacturing the light emitter 5. As described above, the nanocolumns 31 are made of gallium (Ga) contained in the first molecular beam M1, nitrogen (N) contained in the second molecular beam M2, and silicon (Si) contained in the third molecular beam.

In the process of forming the plurality of nanocolumns 31, as shown in FIG. 5, the substrate 100 is first mounted on the mounting portion 220 of the stage 210 such that the surface 100a of the substrate 100 is exposed to the molecular beam through hole 224. The control unit 300 confirms in advance, from at least each of the first molecular beam source 251, the second molecular beam source 252, and the third molecular beam source, that the first molecular beam M1, the second molecular beam M2, and the third molecular beam of the predetermined radiation amount can be radiated. Subsequently, as shown in FIGS. 5 to 7, the control unit 300 rotates the shutter body 282 in the circumferential direction θ, and superimposes the molecular beam passage hole 278 on the molecular beam passage hole 271 in the XY plane. The control unit 300 further rotates the stage body 212 in the circumferential direction θ, and superimposes the mounting portion 220 on the molecular beam passage hole 271 in the XY plane. Under the control of the control unit 300, the first molecular beam M1 is emitted parallel to the Z direction from the molecular beam radiation port 261 of the first molecular beam source 251, and the openings 137 of the substrate 100 are irradiated with Ga molecules.

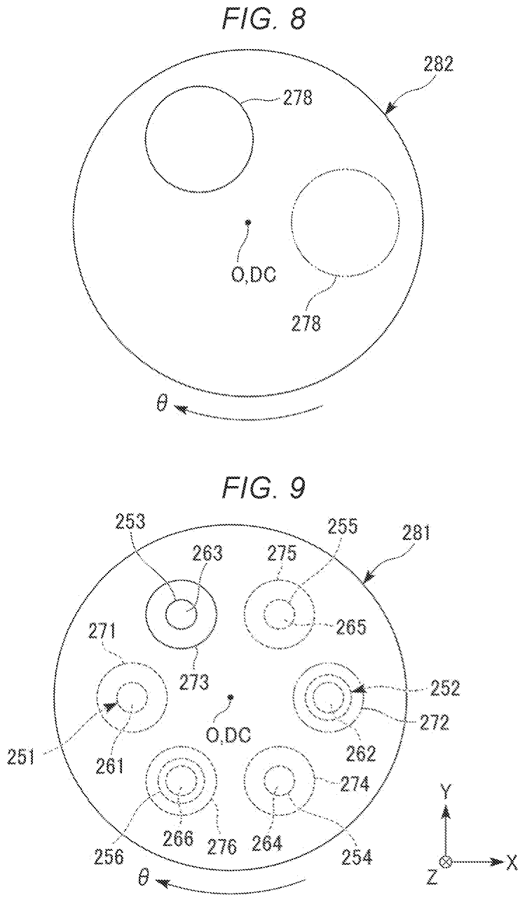

FIG. 8 is a plan view of the shutter body 282 seen from the Z direction at a timing different from that of FIG. 7. FIG. 9 is a plan view of the region where the shutter body 281 and each type of the molecular beam sources are arranged at a timing different from that of FIG. 6 as seen from the Z direction. As described above, after predetermined time elapsed from the start of emission of the first molecular beam M1, the control unit 300 rotates, as shown in FIGS. 7 and 8, the shutter body 282 in the circumferential direction θ to superimpose the molecular beam passage hole 278 on the molecular beam passage hole 273 in the XY plane. The control unit 300 further rotates the stage body 212 in the circumferential direction θ to superimpose the mounting portion 220 on the molecular beam passage hole 273 in the XY plane. Under the control of the control unit 300, the third molecular beam is emitted parallel to the Z direction from the molecular beam radiation port 263 of the third molecular beam source 253, and the openings 137 of the substrate 100 are irradiated with Si molecules.

As described above, after predetermined time elapsed from the start of emission of the third molecular beam, the control unit 300 rotates, as shown by the alternate long and short dash line in FIGS. 7 and 8, the shutter body 282 in the circumferential direction θ, and superimposes the molecular beam passage hole 278 on the molecular beam passage hole 272 in the XY plane. The control unit 300 further rotates the stage body 212 in the circumferential direction θ, and superimposes the mounting portion 220 on the molecular beam passage hole 272 in the XY plane. Under the control of the control unit 300, as shown by the alternate long and short dash line in FIG. 5, the second molecular beam M2 is emitted parallel to the Z direction from the molecular beam radiation port 262 of the second molecular beam source 252, and the openings 137 of the substrate 100 is irradiated with N molecules.

As can be seen with reference to FIGS. 5 to 9, in the MBE apparatus 201, at a certain time and timing, only one type of the molecular beams is radiated to the surface 100a of the substrate 100. That is, in the above process, the Ga molecule contained in the first molecular beam M1, the Si molecule contained in the third molecular beam, and the N molecule contained in the second molecular beam M2 are sequentially, not simultaneously, radiated to the openings 137 of the substrate 100. By appropriately setting the predetermined time for radiating each of the first molecular beam M1 to the third molecular beam, the Si molecules and the N molecules are incorporated into the Ga molecules that reach the openings 137 of the substrate 100, and Si-doped GaN crystals grow along the Z direction. That is, by such migration-enhanced epitaxy (MEE), the Si-doped GaN can be grown parallel to the Z direction without applying excessive energy to the surface 12a of the semiconductor layer 12 exposed in the openings 137 and a growth surface of a crystal column. It is preferable to set the predetermined time to radiate each of the first molecular beam M1 to the third molecular beam based on average lifetime until atoms contained in each of the first molecular beam M1 to the third molecular beam are incorporated as the crystals.

By the above-described processes, the first semiconductor layer 33 made of the Si-doped GaN crystals in the openings 137 of the substrate 100 and having a predetermined dimension in the Z direction is obtained. Subsequently, as in the case of forming the first semiconductor layer 33, the control unit 300 selects the molecular beam source to be used according to the crystal material of the light emitting layer 34 to form the light emitting layer 34 at the first semiconductor layer 33. Further, as in the case of forming the first semiconductor layer 33, the control unit 300 selects the molecular beam source to be used according to the crystal material of the light emitting layer 34 to form the light emitting layer 34 at the first semiconductor layer 33 by the MEE.

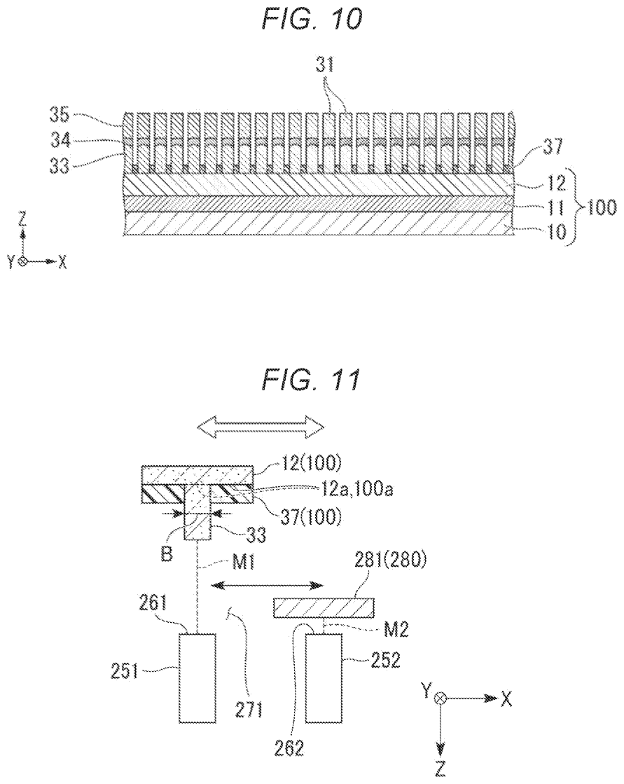

Next, the control unit 300 selects the first molecular beam source 251, the fifth molecular beam source 255, and the second molecular beam source 252 as the molecular beam sources according to the crystal material of the second semiconductor layer 35 to form the second semiconductor layer 35 at the light emitting layer 34. FIG. 10 is a cross-sectional view showing a process of the method for manufacturing the light emitter 5. By the above-described processes, as shown in FIG. 10, the plurality of nanocolumns 31 with shaft core directions parallel to the Z direction can be simultaneously formed at the surface 100a of the substrate 100.

After the above-described processes, although not shown in the drawings, an insulating layer is formed around the nanocolumns 31 in the XY plane to form the light propagation layer 32. When the light propagation layer 32 is formed by, for example, the atomic layer deposition (ALD) method, the light propagation layer 32 can be formed even in fine gaps between the nanocolumns 31 in the XY plane.

Next, the substrate 100 at which the plurality of nanocolumns 31 are formed is taken out from the mounting portion 220 of the MBE apparatus 201. During the formation of the plurality of nanocolumns 31 substantially over the entire surface 100a of the substrate 100 by photolithography and etching using a resist pattern (not shown), a plurality of nanocolumns 31 that do not overlap the light emitting units 30 are patterned in the Z direction.

Next, the insulating layer 40 is formed to fill the space between the plurality of nanocolumns 31 for each of the light emitting units 30. At this time, the insulating layer 40 can be formed by a coating method such as spin coating. It is preferable that the thickness of the insulating layer 40, that is, the dimension in the Z direction is the same as the height of the nanocolumns 31 or thicker than the height of the nanocolumns 31.

Next, the second electrode 60 that is electrically coupled to each of the plurality of nanocolumns 31 is formed. Specifically, the second electrode 60 is formed by forming and patterning a metal film or a transparent conductive layer by, for example, the sputtering method or the vacuum vapor deposition method. Subsequently, the wirings 70 are formed by performing film formation and patterning by the sputtering method or the vacuum vapor deposition method. By the above-described processes, a light emitting apparatus 1 shown in FIGS. 1 and 2 is completed. Further, various processes such as formation of the first electrode 50, mounting of the drive circuit, and electrical coupling between the drive circuit and the first electrode 50 and the second electrode 60 by wire bonding are performed.

The MBE apparatus 201 according to the first embodiment described above includes the stage 210, the first molecular beam source 251, the second molecular beam source 252, the shutter 280, and the control unit 300. The stage 210 includes the mounting portion 220 on which the substrate 100 is mounted. The first molecular beam source 251 irradiates the surface 100a of the substrate 100 with the first molecular beam M1. The second molecular beam source 252 irradiates the surface 100a of the substrate 100 with the second molecular beam M2. The shutter 280 shields the first molecular beam M1 or the second molecular beam M2. The control unit 300 controls the operations of the shutter, the relative positions of the stage with respect to the first molecular beam source and the second molecular beam source. In the MBE apparatus 201, the radiation direction of the first molecular beam M1 radiated from the first molecular beam source 251 and the radiation direction of the second molecular beam M2 radiated from the second molecular beam source 252 are vertical to the surface 100a of the substrate 100 mounted on the mounting portion 220. Under the control of the control unit 300, the second molecular beam M2 is shielded while the first molecular beam M1 is radiated on the surface 100a of the substrate 100, and the first molecular beam M1 is shielded while the second molecular beam M2 is radiated on the surface 100a.

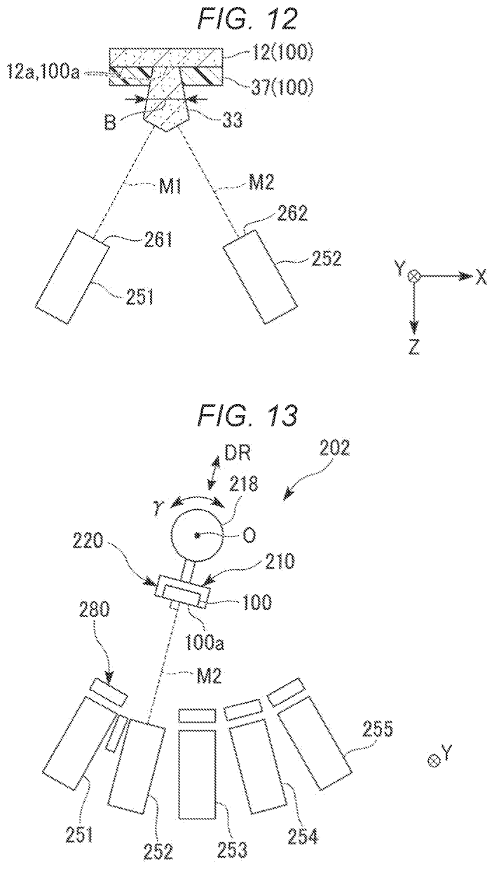

FIG. 11 is a schematic configuration diagram of main parts of the MBE apparatus 201 according to the first embodiment. FIG. 12 is a schematic configuration diagram of main parts of a related-art MBE apparatus. In the MBE apparatus 201 according to the first embodiment, as shown in FIG. 11, at least the radiation directions of the first molecular beam M1 and the second molecular beam M2 are vertical to the surface 100a of the substrate 100. The shutter 280 is synchronized with the rotation of the stage 210 and the accompanying movement of the substrate 100. According to the MBE apparatus 201 according to the first embodiment, at one moment, only one type of the molecular beams from one of the molecular beam sources, for example, only the first molecular beam M1 from the first molecular beam source 251 is radiated on the surface 100a of the substrate 100. However, under the control of the control unit 300, the surface 100a of the substrate 100 can be irradiated with a plurality of types of molecular beams in a time-division manner by moving or rotating the stage 210 and the shutter 280. Thus, the radiation directions of the first molecular beam M1 and the second molecular beam M2 are aligned in the Z direction, that is, in a direction nearly vertical to the surface 100a of the substrate 100, and the growth direction and the column center direction of, for example, the first semiconductor layer 33 of the nanocolumn 31 by the MEE method can be made parallel to the Z direction. As a result, a width dimension B in the direction orthogonal to the growth direction and the column center direction of the nanocolumn 31 is made substantially uniform in the Z direction, and the width dimension B can be controlled with high accuracy by the control unit 300 controlling the radiation amount of each of the molecular beams. Thus, according to the MBE apparatus 201 according to the first embodiment, the light emitting efficiency of the light emitter 5 to be manufactured can be improved.

On the other hand, as shown in FIG. 12, in the configuration of the related-art MBE apparatus, diagonal deposition is performed at an angle of, for example, about 45° with respect to the direction vertical to the surface 100a of the substrate 100. Thus, the width dimension B of, for example, the first semiconductor layer 33 of the nanocolumn 31 becomes larger as the first semiconductor layer 33 grows, and the light emitting efficiency of the light emitter 5 may decrease.

In the MBE apparatus 201 according to the first embodiment, the stage 210 is relatively movable, and is rotatable in the circumferential direction θ. When the surface 100a of the substrate 100 is aligned with the molecular beam radiation port 261 (one molecular beam radiation port of the molecular beam radiation port 261 of the first molecular beam source 251 and the molecular beam radiation port 262 of the second molecular beam source 252) by moving or rotating the stage 210, the control unit 300 opens the molecular beam radiation port 261 while closing the molecular beam radiation port 262 (the other molecular beam radiation port). At this time, the control unit 300 operates the shutter 280 to shield the second molecular beam M2 radiated from the molecular beam radiation port 262.

In the MBE apparatus 201 according to the first embodiment, specifically, the stage 210 includes the plate-shaped stage body 212, and the mounting portion 220 on which the substrate 100 is mounted is provided at one plate surface 212b of the stage body 212. The stage body 212 is rotatable with respect to the center O. The shutter 280 includes the plate-shaped shutter bodies 281 and 282. The shutter body 281 is aligned with the stage body 212. The second shutter body 282 is arranged between the stage body 212 and the shutter body 281 in the thickness direction of the stage body 212, that is, in the Z direction. In the shutter body 281, a molecular beam passage hole (first molecular beam passage hole) is formed at a position overlapping the molecular beam radiation port 261 of the first molecular beam source 251 in a direction parallel to the surface 100a of the substrate 100, and another molecular beam passage hole is formed at a position overlapping the molecular beam radiation port 262 of the second molecular beam source 252 in a direction parallel to the surface 100a. The molecular beam passage hole 278 is formed in the shutter body 282. The shutter body 282 is rotatable coaxially with the stage body 212 in the circumferential direction θ such that the molecular beam passage hole 271 or the molecular beam passage hole 272 overlaps the mounting portion 220 in a direction in which the molecular beam passage hole 278 is parallel to the surface 100a.

In the MBE apparatus 201 according to the first embodiment, the stage body 212 on which the substrate 100 is mounted and the shutter body 282 can be synchronized, and the surface 100a of the substrate 100 can be irradiated with the first molecular beam M1 or the second molecular beam M2. According to the MBE apparatus 201 according to the first embodiment, the shutter 280 has a double structure.

According to the MBE apparatus 201 according to the first embodiment, any of the molecular beam passage holes 271 to 276, through which the molecular beams are radiated on the surface 100a of the substrate 100, is aligned with the molecular beam passage hole 278, and a molecular beam is emitted from a molecular beam source in which any one of the molecular beam passage holes 271 to 276 communicates the molecular beam passage hole 278. In this configuration, the molecular beam passage holes of all the types of molecular beam sources can be easily closed while the molecular beam passage hole 278 rotates from one molecular beam source to another. According to the MBE apparatus 201 according to the first embodiment, it is possible to reduce loads on the stage 210 and the shutter 280 during the rotation and movement operations.

According to the crystal growth method and the method for manufacturing the light emitter according to the first embodiment, the first molecular beam M1, the second molecular beam M2, and the third molecular beam to the sixth molecular beam are radiated on the surface 100a of the substrate 100 to grow the nanocolumn 31 made of materials contained in at least the first molecular beam M1 and the second molecular beam M2 along the direction vertical to the surface 100a. In this process, the first molecular beam M1 to the sixth molecular beam are radiated individually on the surface 100a from different positions such that the radiation directions of the first molecular beam M1 to the sixth molecular beam are parallel to the direction vertical to the surface 100a, and the second molecular beam M2 to the sixth molecular beam are shielded under the control of the control unit 300 while the first molecular beam M1 is radiated on the surface 100a of the substrate 100, and the first molecular beam M1 and the third molecular beam to the sixth molecular beam are shielded under the control of the control unit 300 while the second molecular beam M2 is radiated on the surface 100a. According to the crystal growth method and the method for manufacturing the light emitter according to the first embodiment, the width dimension B in the direction orthogonal to the growth direction and the column center direction of the nanocolumn 31 is substantially uniform in the Z direction, and the width dimension B can be controlled with high accuracy by the control unit 300 controlling the radiation amount of each of the molecular beams. Thus, the light emitting efficiency of the light emitter 5 to be manufactured can be improved.

### Second Embodiment

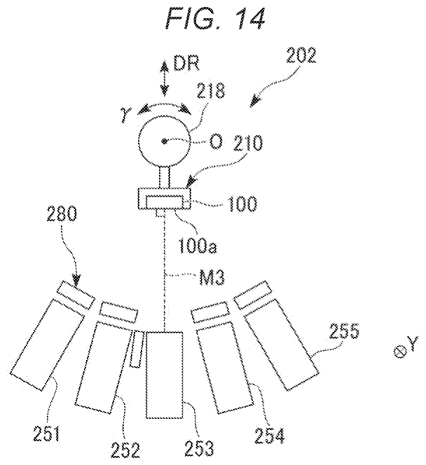

Next, a MBE apparatus according to the second embodiment of the present disclosure will be described with reference to FIGS. 13 and 14.

In the second embodiment, the same components as those in the first embodiment are designated by the same reference numerals as those in the above-described embodiment, and the description thereof will be omitted.

FIG. 13 is a schematic side view of a MBE apparatus 202 according to the second embodiment when viewed from the Y direction. FIG. 14 is a schematic side view when the MBE apparatus 202 is viewed from the Y direction at a timing different from that of FIG. 13. As shown in FIG. 13, in the MBE apparatus 202, the stage 210 is rotatable with respect to the center O, with the direction vertical to the exposed surface 100a of the substrate 100 mounted on the mounting portion 220 as a radial direction DR. The first molecular beam source 251 to the fifth molecular beam source 255 are arranged at different positions on a circumferential direction γ when the stage 210 rotates with respect to the center O. The detectors 290 are omitted in FIGS. 13 and 14.

The stage 210 includes a rotary member 218 rotatable in the circumferential direction γ with respect to the center O and a support member 219 extending along the radial direction DR from a circumferential surface of the rotary member 218 to a side where the first molecular beam source 251 to the fifth molecular beam source 255 are arranged in the radial direction DR. The mounting portion 220 is provided at a top end portion of the support member 219. The support member 219 is rotatable in the circumferential direction γ with respect to the center O. The surface 100a of the substrate 100 mounted on the mounting portion 220 is orthogonal to the radial direction DR.

In the MBE apparatus 202, the radiation directions of all types of molecular beams including the first molecular beam M1 and the second molecular beam M2 are parallel to the radial direction DR. The control unit 300 is omitted in FIGS. 13 and 14. Since the rotary member 218 rotates in the circumferential direction γ under the control of the control unit 300, the surface 100a of the substrate 100 mounted on the mounting portion 220 can be aligned with any of the molecular beam radiation ports 261 to 265 of the first molecular beam source 251 to the fifth molecular beam source 255.

The radiation directions of the first molecular beam M1 to the fifth molecular beam radiated by the first molecular beam source 251 to the fifth molecular beam source 255 are vertical to the surface 100a of the substrate 100 mounted on the mounting portion 220. Each of the first molecular beam source 251 to the fifth molecular beam source 255 is provided with one shutter 280 that can be opened and closed independently. The control unit 300 controls a rotation angle of the rotary member 218 with respect to the center O and the opening and closing of shutters 280 of the plurality of types of molecular beam sources. The second molecular beam M2 and the third molecular beam to the fifth molecular beam are shielded under the control of the control unit 300 while the first molecular beam M1 is radiated on the surface 100a of the substrate 100. As shown in FIG. 13, the first molecular beam M1 and the third molecular beam to the fifth molecular beam are shielded under the control of the control unit 300 while the second molecular beam M2 is radiated on the surface 100a. Moreover, as shown in FIG. 14, the first molecular beam M1, the second molecular beam M2, the fourth molecular beam and the fifth molecular beam are shielded under the control of the control unit 300 while the third molecular beam is radiated on the surface 100a.

Except for using the MBE apparatus 202 according to the second embodiment instead of the MBE apparatus 201 according to the first embodiment, a method for manufacturing the light emitter 5 according to the second embodiment is the same as the method for manufacturing the light emitter 5 according to the first embodiment.

In the MBE apparatus 202 according to the second embodiment, similar to the MBE apparatus 201 according to the first embodiment, the surface 100a of the substrate 100 can be irradiated with a plurality of types of molecular beams in a time-division manner. Thus, the radiation directions of the first molecular beam M1 to the fifth molecular beam are aligned in the direction vertical to the surface 100a of the substrate 100, and the growth direction and the column center direction, for example, of the first semiconductor layer 33 of the nanocolumn 31 by the MEE method can be made vertical to the surface 100a. As a result, the width dimension B in the direction orthogonal to the growth direction and the column center direction of the nanocolumn 31 is made substantially uniform in the Z direction, and the width dimension B can be controlled with high accuracy by the control unit 300 controlling the radiation amount of each of the molecular beams. Thus, according to the MBE apparatus 202 according to the second embodiment, the light emitting efficiency of the light emitter 5 to be manufactured can be improved.

The preferred embodiments of the present disclosure have been described in detail above, and the present disclosure is not limited to the specific embodiments, and various modifications and changes can be made within the scope of the gist of the present disclosure recited in the claims. The components of embodiments can be appropriately combined.

For example, in the MBE apparatus according to the present disclosure, the number of types of molecular beams is not limited to two, and can be appropriately changed depending on structures and materials of the columnar crystal structure and the light emitter to be manufactured. A molecular beam having a small effect on the expansion of the width dimension during the growth of the crystal column, for example, molecular beams of dopants such as Si and Mg, may be radiated on the surface of the substrate together with other molecular beams. In that case, the number and formation positions of the molecular beam through holes in the shutter and the opening and closing structure of the shutter may be appropriately changed by a method such as making the shutter body 281 rotatable. When a quantum well layer made of InGaN or an electron block layer made of AlGaN is inserted into the light emitting layer 34, the quantum well layer made of InGaN may be a molecular beam source of In molecules used as a fourth molecular beam M4, and the electron block layer made of AlGaN may be the molecular beam source of Al molecules used as a sixth molecular beam M6, for example. The combination of the materials of the first molecular beam M1 and the second molecular beam M2 is not limited to the Ga molecules and the N molecules, and may be, for example, a combination of the Ga molecules and As molecules. As another example, Zn molecules and Se molecules may be used. Further, the type and the structure of the light emitter are not limited to those described in the above-described embodiments, and include structures that grow crystals in a direction vertical to the surface of the substrate and can be formed by the MBE method, preferably the MEE method.

The MBE apparatus according to the present disclosure may have the following configurations.

A MBE apparatus according to one embodiment of the present disclosure includes a stage on which an object including a substrate is mounted, a first molecular beam source configured to irradiate the object with a first molecular beam, a second molecular beam source configured to irradiate the object with a second molecular beam, a shutter configured to shield the first molecular beam or the second molecular beam, and a control unit configured to control operations of the shutter and relative positions of the stage with respect to the first molecular beam source and the second molecular beam source. Under the control of the control unit, the second molecular beam is shielded while the first molecular beam is radiated on a surface, and the first molecular beam is shielded while the second molecular beam is radiated on the surface.

In the MBE apparatus according to one embodiment of the present disclosure, the stage is movable in a predetermined direction. When the surface is aligned with a molecular beam radiation port of the first molecular radiation source or a molecular beam radiation port of the second molecular beam source by moving the stage, the control unit may open the aligned molecular beam radiation port while closing the other molecular beam radiation port, and operate the shutter to shield the first molecular beam or the second molecular beam radiated from the aligned molecular beam radiation port.

In the MBE apparatus according to one embodiment of the present disclosure, the stage includes a plate-shaped stage body. A mounting portion on which the substrate is mounted is provided on one plate surface of the stage body, and the stage body is rotatable with respect to a center of the plate surface. The shutter includes a first plate-shaped shutter body facing the stage body and a second plate-shaped shutter body arranged between the stage body and the first shutter body in a thickness direction of the stage body. In the first shutter body, a first molecular beam passage hole is formed at a position overlapping the molecular beam radiation port of the first molecular beam source in a direction parallel to the surface, and a second molecular beam passage hole is formed at a position overlapping the molecular beam radiation port of the second molecular beam source in a direction parallel to the surface. A molecular beam passage hole is formed in the second shutter body. The second shutter body may be rotatable coaxially with the stage body in a circumferential direction such that the first molecular beam passage hole or the second molecular beam passage hole overlaps the mounting portion in a direction in which the molecular beam passage holes are parallel to the substrate surface.

In the MBE apparatus according to one embodiment of the present disclosure, the stage is rotatable in a direction vertical to a substrate surface as a radial direction. The first molecular beam source and the second molecular beam source may be arranged at different positions in a circumferential direction when the stage rotates such that a radiation direction of the first molecular beam and a radiation direction of the second molecular beam are parallel to the radial direction.

In the MBE apparatus according to one embodiment of the present disclosure, the radiation direction of the first molecular beam emitted from the first molecular beam source and the radiation direction of the second molecular beam emitted from the second molecular beam source may be vertical to a substrate surface of the substrate.

A crystal growth method of one embodiment of the present disclosure may include the following procedure.

The crystal growth method according to one embodiment of the present disclosure includes a process of irradiating an object including a substrate with a first molecular beam and a second molecular beam to grow a crystal column made of materials contained in the first molecular beam and the second molecular beam along a direction vertical to a substrate surface of the substrate. In the process of growing the crystal column, the first molecular beam and the second molecular beam are radiated on the substrate surface from different positions such that radiation directions of the first molecular beam and the second molecular beam are parallel to the direction vertical to the substrate surface, the second molecular beam is shielded while the first molecular beam is radiated on the surface, and the first molecular beam is shielded while the second molecular beam is radiated on the surface.

A method for manufacturing a light emitter according to one embodiment of the present disclosure may include the following procedure.

In the method for manufacturing a light emitter according to one embodiment of the present disclosure, the crystal growth method according to the above-described embodiment of the present disclosure is used.

What is claimed is:

1. A molecular beam epitaxial growth apparatus comprising:
a stage on which an object including a substrate is mounted;
a first molecular beam source configured to irradiate the object with a first molecular beam;
a second molecular beam source configured to irradiate the object with a second molecular beam;
a shutter configured to shield the first molecular beam or the second molecular beam; and
a control unit configured to control operations of the shutter and relative positions of the stage with respect to the first molecular beam source and the second molecular beam source, wherein
When the first molecular beam is radiated on the substrate, the control unit controls the shutter to shield the second molecular beam, and
when the second molecular beam is radiated on the substrate, the control unit controls the shutter to shield the first molecular beam.

2. The molecular beam epitaxial growth apparatus according to claim 1, wherein
the stage is movable in a predetermined direction, and
when the stage is moved, and a molecular beam radiation port of the first molecular radiation source or a molecular beam radiation port of the second molecular beam source is aligned with the object thereby, the control unit operates the shutter so as to open the aligned molecular beam radiation port, to close the other molecular beam radiation port, and to shield the first molecular beam or the second molecular beam radiated from the aligned molecular beam radiation port.

3. The molecular beam epitaxial growth apparatus according to claim 2, wherein
the stage includes a plate-shaped stage body,
a mounting portion on which the object is mounted is provided at one plate surface of the stage body,
the stage body is rotatable with respect to a center of the plate surface,
the shutter includes a first plate-shaped shutter body facing the stage body and a second plate-shaped shutter body arranged between the stage body and the first shutter body in a thickness direction of the stage body,
in the first shutter body, a first molecular beam passage hole is formed at a position overlapping the molecular beam radiation port of the first molecular beam source in a direction parallel to a substrate surface, and a second molecular beam passage hole is formed at a position overlapping the molecular beam radiation port of the second molecular beam source in a direction parallel to the substrate surface,
a molecular beam passage hole is formed in the second shutter body, and
the second shutter body is rotatable coaxially with the stage body in a circumferential direction such that the first molecular beam passage hole or the second molecular beam passage hole overlaps the mounting portion in a direction in which the molecular beam passage holes are parallel to the substrate surface.

4. The molecular beam epitaxial growth apparatus according to claim 2, wherein
the stage is rotatable in a direction vertical to a substrate surface as a radial direction, and
the first molecular beam source and the second molecular beam source are arranged at different positions in a circumferential direction when the stage rotates such that a radiation direction of the first molecular beam and a radiation direction of the second molecular beam are parallel to the radial direction.

5. The molecular beam epitaxial growth apparatus according to claim 1, wherein
the radiation direction of the first molecular beam emitted from the first molecular beam source and the radiation direction of the second molecular beam emitted from the second molecular beam source are vertical to a substrate surface of the substrate.

6. A crystal growth method comprising:
a process of irradiating an object including a substrate with a first molecular beam and a second molecular beam to grow a crystal column made of materials contained in the first molecular beam and the second molecular beam along a direction vertical to a substrate surface, wherein
in the process of growing the crystal column, the first molecular beam and the second molecular beam are radiated on the substrate surface from different positions such that radiation directions of the first molecular beam and the second molecular beam are parallel to the direction vertical to the substrate surface, and
the second molecular beam is shielded when the first molecular beam is radiated on the object, and the first molecular beam is shielded when the second molecular beam is radiated on the substrate surface.

7. A method for manufacturing a light emitter, wherein
the crystal growth method according to claim 6 is used.
